(19) United States
(12) Patent Application Publication
(10) Pub. No.: US 2025/0373144 A1
(43) Pub. Date: Dec. 4, 2025

(54) ADAPTIVE SLEW RATE DRIVER

(71) Applicant: TEXAS INSTRUMENTS INCORPORATED, Dallas, TX (US)

(72) Inventors: Amal Kumar Kundu, Bangalore (IN); Piranave K A, Bengaluru (IN); Anant Shankar Kamath, Bangalore (IN)

(21) Appl. No.: 18/679,221

(22) Filed: May 30, 2024

(51) Int. Cl. H02M 1/088; H02M 1/00; H02M 3/157; H02M 3/158

(52) U.S. Cl. CPC H02M 1/088; H02M 1/0045; H02M 1/0054; H02M 3/157; H02M 3/158

(57) ABSTRACT

An apparatus includes a first transistor having a control input. The apparatus also includes a driver having an output coupled to the control input. The driver includes an adaptive slew rate control circuit having an input coupled to a first terminal. The adaptive slew rate control circuit is configured to control the slew rate of the first transistor based on a resistor coupled to the first terminal.

### BACKGROUND

Switching power converters include one or more transistors that are turned on and off during each switching cycle of, for example, a pulse width modulation (PWM) signal. A driver is coupled to the gate of each such transistor. A control signal, e.g., the PWM signal, received by each driver causes the driver to turn on or off the corresponding transistor. To turn on the transistor, a driver provides current to the gate capacitance of the transistor to charge the gate capacitance. To turn off the transistor, the driver provides a discharge current path to discharge the gate capacitance. If the gate driver is too strong (gate's pull-up resistance/pull-down resistance is too low), the voltage at the switch node may overshoot and cause ringing which may damage the transistor over time. A weak gate driver turns the transistor on and off slowly thereby increasing the switching losses in the transistor.

### SUMMARY

In one example, an apparatus includes a first transistor having a control input. The apparatus also includes a driver having an output coupled to the control input. The driver includes an adaptive slew rate control circuit having an input coupled to a first terminal. The adaptive slew rate control circuit is configured to control the slew rate of the first transistor based on a resistor coupled to the first terminal.

In another example, an apparatus includes transistors having control inputs, first terminals, and second terminals. The first terminals are coupled together, and the second terminals are coupled together. A bandgap voltage reference circuit has a first voltage terminal coupled to the first terminals and has a second voltage terminal. A comparator has a first comparator input, a second comparator input, and a comparator output. The first comparator input is coupled to the second voltage terminal, and the second comparator input is coupled to the second terminals. A current source circuit is coupled to the second terminals. A logic circuit has an input coupled to the comparator output and has outputs coupled to respective control inputs of the transistors.

In yet another example, a power converter includes a first transistor having a control input and a second transistor coupled to the first transistor. The second transistor has a control input. A first driver has an output coupled to the control input of the first transistor. The first driver includes a first adaptive slew rate control circuit having an input coupled to a first terminal. The first adaptive slew rate control circuit is configured to control the slew rate of the first transistor based on a first resistor coupled to the first terminal. A second driver has an output coupled to the control input of the second transistor. The second driver includes a second adaptive slew rate control circuit having an input coupled to a second terminal. The second adaptive slew rate control circuit is configured to control the slew rate of the second transistor based on a second resistor coupled to the second terminal.

### BRIEF DESCRIPTION OF THE DRAWINGS

FIG. 1 is a block diagram of a power converter including adaptive slew rate drivers, in an example.

FIG. 2 is a schematic diagram of the adaptive slew rate drivers of FIG. 1, in an example.

FIG. 3 is a schematic diagram of an adaptive slew rate control circuit for one of the adaptive slew rate drivers of FIG. 2, in an example.

FIG. 4 is a schematic diagram of an adaptive slew rate control circuit for the other adaptive slew rate driver of FIG. 2, in an example.

FIG. 5 is a flow chart illustrating the operation of the adaptive slew rate control circuits, in an example.

FIG. 6 is a schematic diagram of a bandgap voltage reference circuit for use in the adaptive slew rate control circuits, in an example.

FIG. 7 is a schematic diagram of a current source circuit for use in the adaptive slew rate control circuit of FIG. 3, in an example.

FIG. 8 is a schematic diagram of a current source circuit for use in the adaptive slew rate control circuit of FIG. 4, in an example.

FIG. 9 is a schematic diagram of a current source circuit including temperature compensation, in an example.

### DETAILED DESCRIPTION

The same reference numbers or other reference designators are used in the drawings to designate the same or similar (either by function and/or structure) features.

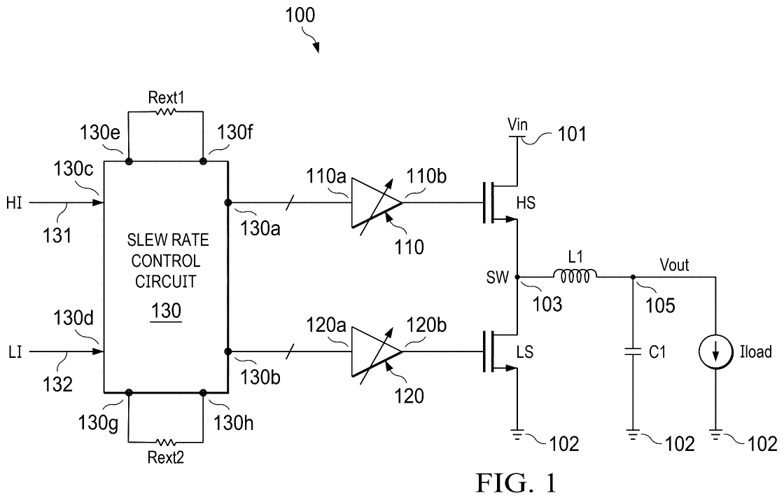

FIG. 1 is a block diagram of a power converter 100, in an example. In this example, power converter 100 is a switching power converter including a high side (HS) transistor and a low side (LS) transistor coupled in series between a power terminal 101 (VIN) and a ground terminal 102. Power converter 100 also includes drivers 110 and 120 and a slew rate control circuit 130. The HS and LS transistors may be field effect transistors (FETs). In an example, the HS and LS transistors are gallium nitride (GaN) transistors. Both the HS and LS transistors may be n-channel FETS (NFETs). The drain of the HS transistor is coupled to the power terminal 101. The source of the HS transistor is coupled to the drain of the LS transistor at the switch (SW) terminal 103. The source of the LS transistor is coupled to the ground terminal 102. One terminal of an inductor L1 is coupled to the SW terminal 103. A capacitor C1 is coupled between the other terminal of the inductor L1 at the output terminal 105 (Vout) and the ground terminal 102. Current Iload represents the current drawn by a load coupled to the output terminal 105.

Each of the HS and LS transistors are driven by a respective driver 110 and 120. Driver 110 has an input 110a and an output 110b. Output 110b is coupled to the gate of the HS transistor. Similarly, driver 120 has an input 120a and an output 120b. Output 120b is coupled to the gate of the LS transistor. The arrows through drivers 110 and 120 indicate that the drivers have a programmable drive strength. Slew rate control circuit 130 has inputs 130c and 130d, which receive respective signals HI 131 and L1 132. HI signal 131 indicates when the HS transistor is to be on and off, and L1 signal 132 indicates when the LS transistor is to be on and off. Slew rate control circuit 130 has an output 130a coupled to input 110a of driver 110 and an output 130b coupled to input 120a of driver 120.

Slew rate control circuit includes terminals 130c, 130f, 130g, and 130h. External resistors (e.g., external to the integrated circuit containing slew rate control circuit 130) can be coupled to terminals 130c, 130f, 130g, and 130h. FIG. 1 shows a resistor Rext1 coupled to terminals 1303 and 130f and a resistor Rext2 coupled to terminals 130g and 130h. Slew rate control circuit 130 provides signals to inputs 110a and 120a of drivers 110 and 120 to turn on the respective HS and LS transistors with a drive strength programmed by the value of resistor Rext1. Similarly, slew rate control circuit 130 provides signals to inputs 110a and 120a of drivers 110 and 120 to turn off the respective HS and LS transistors with a drive strength programmed by the value of resistor Rext2.

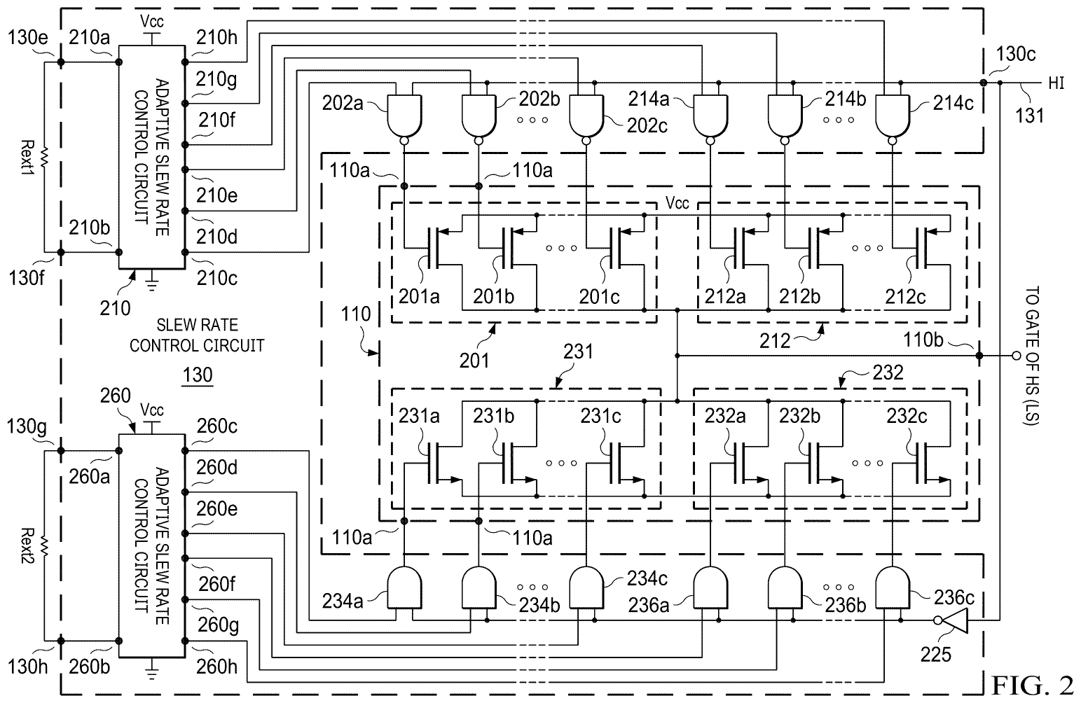

FIG. 2 is a schematic diagram of driver 110 and slew rate control circuit 130 in an example. The schematic diagram for driver 120 and slew rate control circuit 130 is the same or similar. Slew rate control circuit 130 includes adaptive slew rate control circuits 210 and 260, NAND gates 202a, 202b, 202c, 214a, 214b, and 214c, AND gates 234a, 234b, 234c, 236a, 236b, and 236c, and inverter 225. Driver 110 includes transistor arrays 201, 212, 231, and 232. Transistor array 201 includes p-channel field effect transistors (PFETs) 201a, 201b, and 201c. Transistor array 212 includes PFETs 212a, 212b, and 212c. Transistor array 231 includes NFETs 231a, 231b, and 231c. Transistor array 232 includes NFETs 232a, 232b, and 232c. While three transistors are shown within each transistor array 201, 212, 231, and 232, a number of transistors other than three may be included within each transistor array. In one example, each of transistor arrays 201, 212, 231, and 232 includes eight transistors. The sources of transistors 201a-201c and 212a-212c are coupled together as are their drains. Similarly, the sources of transistors 231a-231c and 232a-232c are coupled together as are their drains. The drains of transistors 201a-201c, 212a-212c, 231a-231c, and 232a-232c are coupled together and to the output 110b of driver 110.

The output of each of the NAND and AND gates is coupled to the gate of a corresponding PFET or NFET. The outputs of NAND gates 202a, 202b, and 202c are coupled to the gates of respective transistors 201a, 201b, and 201c. The outputs of NAND gates 214a, 214b, and 214c are coupled to the gates of respective transistors 212a, 212b, and 212c. The outputs of AND gates 234a, 234b, and 234c are coupled to the gates of respective transistors 231a, 231b, and 231c. The outputs of AND gates 236a, 236b, and 236c are coupled to the gates of respective transistors 232a, 232b, and 232c.

The transistors 201a-201c of transistor array 201 are larger than the transistors 212a-212c in transistor array 212. The size of a transistor refers to the ratio of its channel width (W) to its channel length (L). The value of L generally may be the same among all of the transistors in transistor array 201, 212, 231, and 232, but the value of W can vary. Accordingly, the channel width W (and, accordingly, the size) of each of transistors 201a-201c, and the channel width W/size of each of transistors 212a-212c is the same, but the channel width/size of transistors 201-201c is larger than the channel width/size of transistors 212a-212c. In one example, the size of transistors 201a-201c is eight times that of transistors 212a-212c. Similarly, the size among transistors 231a-231c is the same and is eight times that of transistors 232a-232c. The on-resistance of a transistor is a function its size/channel width. A first transistor being eight times the size of a second transistor has one-eighth the on-resistance compared to the second transistor, all else being equal.

The HI signal 131 is provided to an input of inverter 225 and one input of each of NAND gates 202a-202 and 214a-214c. The output of inverter 225 is coupled to one input of each of AND gates 234a-234c and 236a-236c. The other inputs of NAND gates 202a-202 and 214a-214c and AND gates 234a-234c and 236a-236c are coupled to respective outputs of adaptive slew rate control circuits 210 and 260. Adaptive slew rate control circuit 210 includes inputs 210a and 210b (coupled to terminals 130c/130f and 130g/130h, respectively) and outputs 210c, 210d, 210c, 210f, and 210g. Outputs 210c-210g are coupled to respective inputs of NAND gates 202a-202c and 214a-214c. Adaptive slew rate control circuit 260 includes inputs 260a and 260b and outputs 260c, 260d, 260c, 260f, and 260g. Outputs 260c-260g are coupled to respective inputs of AND gates 234a-234c and 236a-236c.

A NAND gate 202a-202c, 214a-214c produces a logic low output signal if both of inputs are logic high. A logic low at the output of any of NAND gates 202a-202c, 214a-214c turns on the corresponding PFET 201a-201c, 212a-212c. Both inputs to any one of NAND gate 202a-202c, 214a-214c are logic high if control signal HI 131 is logic high and adaptive slew rate control circuit 210 generates a logic high signal at an output 210c-210g coupled to the other input of the NAND gate. For example, NAND gate 202a turns on transistor 201a when the control signal HI 131 is logic high and adaptive slew rate control circuit 210 generates a logic high at its output 210c. If either or both of the control signal HI 131 or a signal from the corresponding output of adaptive slew rate control circuit 210 to a NAND gate 202a-202c, 214a-214c is logic low, the output signal from the NAND gate is logic high and the respective transistor 201a-201c, 212a-212c is off. Each of AND gates 234a-234c and 236a-236c produces an output logic high signal to turn on the respective transistor 231a-231c, 232a-232c if the control signal HI 131is logic low and a signal from a respective output 260c-260h is logic high. Otherwise, if an output 260c-260h is logic low and/or the control signal HI 131 is logic low, the respective transistor 231a-231c, 232a-232c is off.

Through their output signals at outputs 210c-210h and 260c-260h, adaptive slew rate control circuits 210 and 260 control which of the transistors within transistor arrays 201, 212, 231, and 232 are on or off when the control signal HI 131 is at a logic state to otherwise cause the transistors within a given transistor to turn on. Accordingly, adaptive slew rate control circuits 210 and 260 control the drive strength to the gate of the HS transistor (or LS transistor in the case of driver 120).

When a transistor within transistor arrays 201, 212 is on, that transistor is operated in its linear region which represents a resistance to the flow of current through the transistor to the gate of the HS transistor. Each of the transistors within transistor array 201 has approximately the same resistance when on, and similarly, each of the transistors within transistor array 212 has approximately the same resistance when on. Because the transistors of transistor array 201 are larger than the transistors of transistor array 212, the on-resistance of the transistors of transistor array 201 is smaller than the on-resistance of the transistors of transistor array 212. The effective resistance of the combined transistors within transistor arrays 201, 212 that are on when turning on the HS transistor is the resistance of a parallel combination of transistor on-resistances. The effective resistance, and accordingly the charge current to the gate of the HS transistor, can be controlled by determining the number of transistors to turn on within each transistor array 201, 212.

The slew rate for turning on the HS transistor can be programmed into the adaptive slew rate control circuit 210 by way of resistor Rext1 coupled to inputs 210a and 210b of adaptive slew rate control circuit 210. As will be explained in greater detail below, resistor Rext1 is used by adaptive slew rate control circuit 210 to control the number of transistors that are on within each of transistor arrays 201 and 212 to thereby control the magnitude of the charge current to the gate of the HS transistor. Similarly, the slew rate for turning off the HS transistor can be programmed into the adaptive slew rate control circuit 260 by way of resistor Rext2 coupled to inputs 260a and 260b of adaptive slew rate control circuit 260. Table I below provides an example of the resistance of resistors Rext1 and Rext2 for different slew rates. For example, for a slew rate of 12 V/ns to turn on and off the HS transistor, the resistance of resistor Rext1 and Rext2 should be 8000 ohms. By coupling an 8000-ohm resistor as resistors Rext1 and Rext2 to the respective adaptive slew rate control circuits 210, 260, the adaptive slew rate control circuits 210, 260 generate signals at their respective outputs 210c-210h and 260c-260h to control which transistors within the transistor arrays 201, 212, 231, and 232 will be on when driver 110 turns on and off the HS transistor. The righthand column of Table I indicates what the effective resistance will be for those transistors within arrays 201, 212 and within arrays 231, 232 when turning on and off the HS transistor.

TABLE I

| | Rext1, Rext2 | |
|---|---|---|
| slew rate (V/ns) | (ohm) | Rout (ohm) |
| 12 | 8000 | 8 |
| 24 | 4000 | 4 |
| 36 | 2667 | 2.666666667 |
| 48 | 2000 | 2 |
| 60 | 1600 | 1.6 |
| 72 | 1333 | 1.333333333 |
| 84 | 1143 | 1.142857143 |
| 96 | 1000 | 1 |

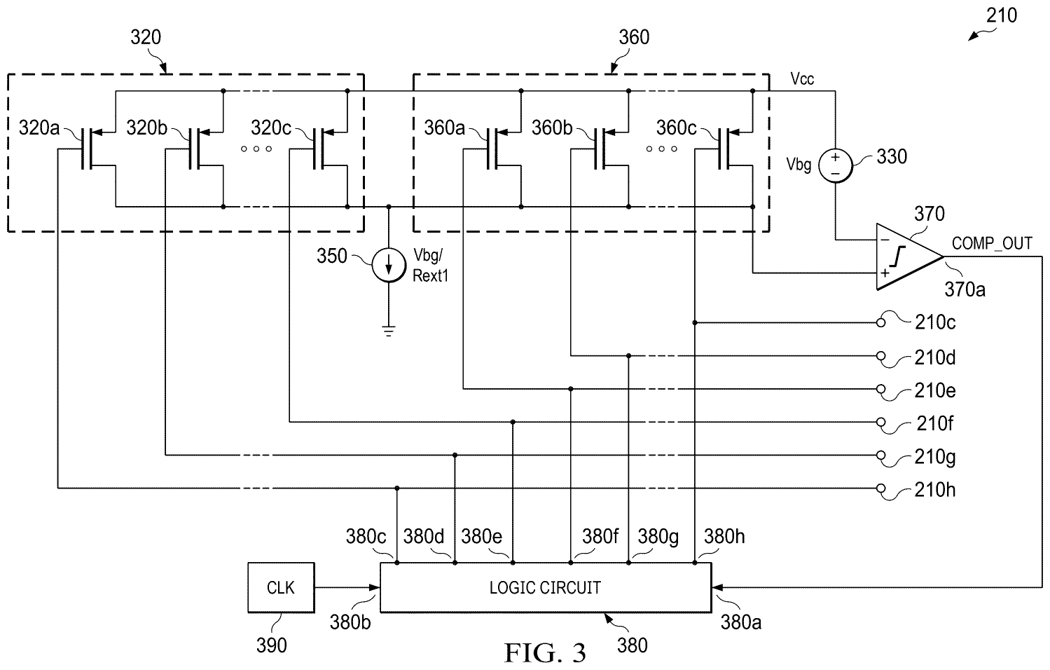

FIG. 3 is a schematic diagram of adaptive slew rate control circuit 210. Adaptive slew rate control circuit 210 includes transistor arrays 320 and 360, a bandgap voltage reference circuit 330, a current source circuit 350, a comparator 370, a logic circuit 380, and a clock circuit 390. Transistor array 320 includes transistors 320a, 320b, and 320c, and transistor array 360 includes transistors 360a, 360, and 360c. The transistors of transistor arrays 320 and 360 are PFETs. In one example, the number of transistors within transistor array 320 matches the number of transistors within transistor array 201, and the number of transistors within transistor array 360 matches the number of transistors within transistor array 212. The size of the transistors within transistor array 320 is smaller than the size of the transistors within transistor array 201, and the size of the transistors within transistor array 360 is smaller than the size of the transistors of transistor array 212. In one example, transistors 320a-320c are one thousand times smaller than the size of transistors 201a-201c, and transistors 360-360c are one thousand times smaller than the size of transistors 212a-212c.

The sources of transistors 320a-320c and 360a-360c are coupled together, and the drains of transistors 320a-320c and 360a-360c also are coupled together. The bandgap voltage reference circuit 330 has a positive terminal and a negative terminal. The positive terminal of bandgap voltage reference circuit 330 is coupled to the sources of transistors 320a-320c and 360a-360c, and the negative terminal of bandgap voltage reference circuit 330 is coupled to the negative input of comparator 370. The positive input of comparator 370 is coupled to the drains of transistors 320a-320c and 360a-360c. Current source circuit 350 is coupled between the drains of transistors 320a-320c and 360a-360c and ground. As described below, the current generated by current source circuit 350 is based on the voltage Vbg produced by bandgap voltage reference circuit 330 and the resistance of resistor Rext1. In one example, the current produced by current source circuit 350 is Vbg/Rext1.

Logic circuit 380 has an input 380a, a clock input 380b, and one output coupled to the gate of a corresponding transistor within transistor arrays 320 and 360. For example, logic circuit 380 has outputs 380c, 380d, 380c, 380f, 380g, and 380h coupled to the gates of the respective transistors 320a, 320b, 320c, 360a, 360b, and 360c. A signal at a given output 380c-380h turns on or off the respective transistor within transistor array 320, 360. Comparator 370 has an output 370a that is coupled to input 380a of logic circuit 380.

The voltage at the negative input of comparator 370 is Vcc-Vbg. The current Vbg/Rext1 produced by current source circuit 350 flows through those transistors within transistor arrays 320, 360 that are on. Accordingly, the voltage at the positive input of comparator 370 is Vcc−(Reff*Vbg/Rext1), where Reff is the effective resistance of the transistors within transistor array 320, 360 that are on. Comparator 370 compares the voltages at its positive and negative inputs and produces an output signal COMP_OUT as a logic 1 responsive to the voltage at its positive input being greater than the voltage at its negative input or COMP_OUT as a logic 0 responsive to the voltage at its positive input being smaller than the voltage at its negative input. The voltage at its positive input approximately equals the voltage at its negative input when Reff approximately equals Rext1.

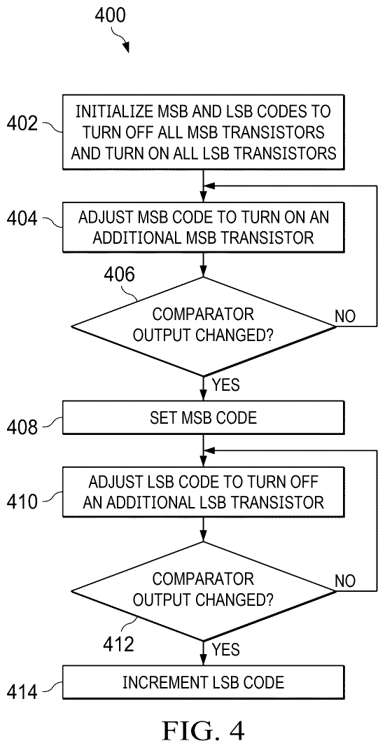

The operation of adaptive slew rate control circuit 210 is described with respect to the flow diagram 400 of FIG. 4 which illustrates a calibration procedure periodically performed (e.g., once per minute) by adaptive slew rate control circuit 210, as well as adaptive slew rate control circuit 260. The operations in flow diagram 400 are performed by logic circuit 380. Logic circuit 380 may include a digital circuit including logic gates, flip-flops, registers, etc.

Reference is made below to most significant bit (MSB) transistors and least significant bit (LSB) transistors. The MSB transistors are transistors 320a-320c within transistor array 320. The LSB transistors are transistors 360a-360c within transistor array 360. The MSB transistors are larger than the LSB transistors as described above. Reference to an MSB code refers to the signals among outputs 380c-380c that turn on/off the MSB transistors. Reference to an LSB code refers to the signals among outputs 380f-380h that turn on/off the LSB transistors.

At operation 402, logic circuit 380 initializes the MSB code and an LSB code to turn off all MSB transistors and turn on all LSB transistors. For example, the initial MSB code may include all logic 1's and the initial LSB code may include all logic 0's. At this state, Reff is small enough such that the voltage at the positive input of comparator 370 is larger than Vbg and COMP_OUT is logic high. With all of the LSB transistors 360a-360b turned on, logic circuit 380 then, using a clock signal from clock circuit 390, sequentially adjusts the MSB code to turn on an additional MSB transistor 320a-320b. Comparator 370 continues to compare, at operation 406, the voltages at its positive and negative inputs. When enough MSB transistors are turned on so that the voltage at the positive input of the comparator approximately equals the voltage at the negative input, COMP_OUT changes logic state from logic high to logic low. At operation 408, logic circuit 380 sets the MSB code to the values of the signals among outputs 380c-380e and makes no further adjustment to the MSB code for the rest of the calibration procedure.

At operation 410, logic circuit 380 then begins to adjust the LSB code to sequentially turn off an additional LSB transistor 360a-360c. As an additional LSB transistor is turned off, comparator 370 determines at operation 412 whether COMP_OUT again changes logic state (e.g., from logic low to back to logic high). If COMP_OUT has not changed logic state, logic circuit 380 turns off an additional LSB transistor at operation 410. Otherwise, if COMP_OUT has changed state, then logic circuit 380 increments the LSB code to turn on one additional LSB transistor, and the calibration procedure ends. The logic state of the signals at outputs 380c-380h are provided through corresponding outputs 210h-210c of adaptive slew rate control circuit 210 to NAND gates 214c, 214b, 214a, 202c, 202b, and 202a to thereby turn on the same number of transistors within transistor array 201 as was the final state for transistor array 320 at the end of the calibration procedure and turn on the same number of transistors within transistor array 212 as was the final state for transistor array 360.

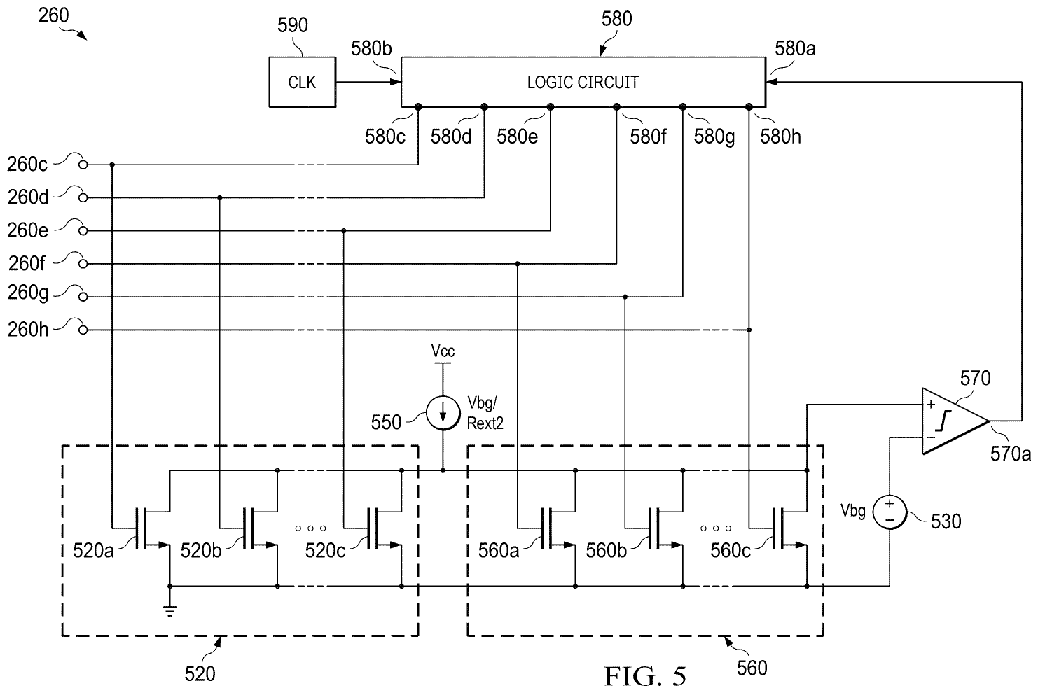

FIG. 5 is a schematic diagram of adaptive slew rate control circuit 260. The architecture of adaptive slew rate control circuit 260 is largely the same as for adaptive slew rate control circuit 210. Adaptive slew rate control circuit 260 includes transistor arrays 520 and 560, a bandgap voltage reference circuit 530, a current source circuit 550, a comparator 570, a logic circuit 580, and a clock circuit 590. Transistor array 520 includes transistors 520a, 520b, and 520c, and transistor array 560 includes transistors 560a, 560, and 560c. The transistors of transistor arrays 520 and 560 are NFETs. In one example, the number of transistors within transistor array 520 matches the number of transistors within transistor array 231, and the number of transistors within transistor array 560 matches the number of transistors within transistor array 232. The size of the transistors within transistor array 520 is smaller than the size of the transistors within transistor array 231, and the size of the transistors within transistor array 560 is smaller than the size of the transistors of transistor array 232. In one example, transistors 520-520c are one thousand times smaller than the size of transistors 231a-231c, and transistors 560-560c are one thousand times smaller than the size of transistors 232a-232c.

The sources of transistors 520a-520c and 560a-560c are coupled together, and the drains of transistors 520a-520c and 560a-560c also are coupled together. The bandgap voltage reference circuit 530 has a positive terminal and a negative terminal. The negative terminal of bandgap voltage reference circuit 530 is coupled to the sources of transistors 520a-520c and 560a-560c, and the positive terminal of bandgap voltage reference circuit 530 is coupled to the negative input of comparator 570. The positive input of comparator 570 is coupled to the drains of transistors 520a-520c and 560a-560c. Current source circuit 550 is coupled between the drains of transistors 520a-520c and 560a-560c and Vcc. The current generated by current source circuit 550 is based on the voltage Vbg produced by bandgap voltage reference circuit 530 and the resistance of resistor Rext2. In one example, the current produced by current source circuit 550 is Vbg/Rext2.

Logic circuit 580 has an input 580a, a clock input 580b, and one output coupled to the gate of a corresponding transistor within transistor arrays 520 and 560. For example, logic circuit 580 has outputs 580c, 580d, 580c, 580f, 580g, and 580h coupled to the gates of the respective transistors 520a, 520b, 520c, 560a, 560b, and 560c. A signal at a given output 580c-580h turns on or off the respective transistor within transistor array 520, 560. Comparator 570 has an output 570a that is coupled to input 580a of logic circuit 580.

The voltage at the negative input of comparator 570 is Vbg. The current Vbg/Rext2 produced by current source circuit 550 flows through those transistors within transistor arrays 520, 560 that are on. Accordingly, the voltage at the positive input of comparator 570 is Reff*Vbg/Rext2, where Reff is the effective resistance of the transistors within transistor array 520, 560 that are on. Comparator 570 compares the voltages at its positive and negative inputs and produces an output signal COMP_OUT as a logic 1 responsive to the voltage at its positive input being greater than the voltage at its negative input or COMP_OUT as a logic 0 responsive to the voltage at its positive input being smaller than the voltage at its negative input. The voltage at its positive input approximately equals the voltage at its negative input when Reff approximately equals Rext2. The operation of adaptive slew rate control circuit 260 is largely the same as that described above for adaptive slew rate control circuit 210.

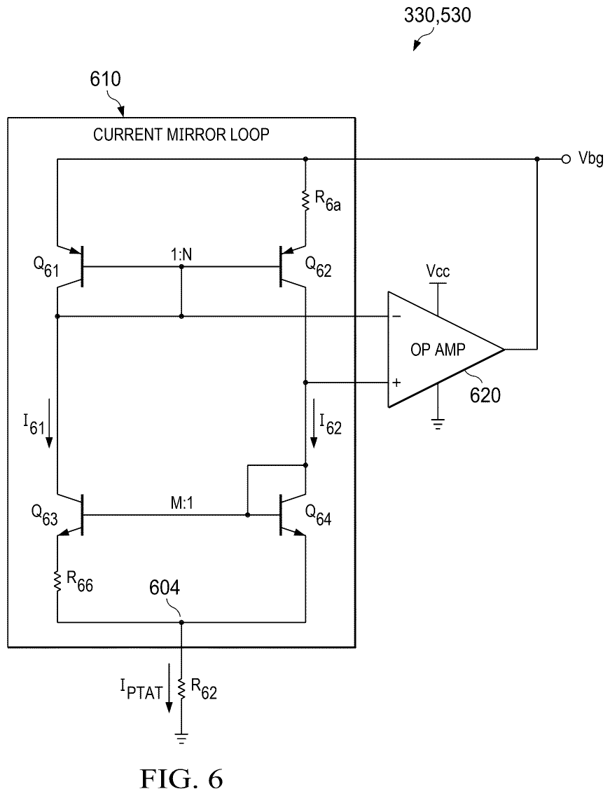

FIG. 6 is a schematic of a bandgap voltage reference circuit usable to implement either or both of bandgap voltage reference circuits 330 and 530, in accordance with an example. In the example of FIG. 6, the bandgap voltage reference circuit 330, 530 includes a current mirror loop 610 and an operational amplifier (OP AMP) 620. The current mirror loop 610 includes transistors Q₆₁, Q₆₂, Q₆₃, and Q₆₄ and resistors R₆ₐ, R_{6b}, and R₆₂. OP AMP 620 includes a negative (−) input, a positive (+) input, and an output. Transistors Q₆₁ and Q₆₂ are PNP bipolar junction transistors (BJTs), and transistors Q₆₃ and Q₆₄ are NPN BJTs. The collectors of transistor Q₆₁ and Q₆₃ are coupled together and to the OP AMP's negative input. The collectors of transistors Q₆₂ and Q₆₄ are coupled together and to the positive input of OP AMP 620. Resistor R₆₂ is coupled between the emitter of transistor Q₆₄ at node 604 and ground. Resistor R_{6b} is coupled between the emitter of transistor Q₆₃ and resistor R₆₂ at node 604. The output of OP AMP 620 is coupled to the emitter of transistor Q₆₁. Resistor R₆ₐ is coupled between the OP AMP's output and the emitter of transistor Q₆₂. The output of the OP AMP 620 provides the output bandgap voltage V_{BG}.

The bases of transistors Q₆₁ and Q₆₂ are coupled together. The ratio of the size of transistor Q₆₁ to transistor Q₆₂ is 1:N. The combination of transistors Q₆₁ and Q₆₂ and resistor R₆ₐ forms a current mirror in which current I₆₁ through transistor Q₆₁ is approximately equal to current I₆₂ through transistor Q₆₂. Similarly, the bases of transistors Q₆₃ and Q₆₄ are coupled together and to the collector of transistor Q₆₄ and to the positive input of OP AMP 620. The ratio of the sizes of transistor Q₆₃ to transistor Q₆₄ is M:1. Transistors Q₆₃ and Q₆₄ are coupled together to form a current mirror in which, for the case in which M equals N, current I₆₁ through transistor Q₆₃ is approximately equal to current I₆₂ through transistor Q₆₄. Currents I₆₁ and I₆₂ add together to form current IPTAT through resistor R₆₂.

For an ideal OP AMP, the voltages on the positive and negative inputs are equal. Accordingly, the output bandgap voltage V_{BG} is the sum of the Vbe_Q1 (Vbe of transistor Q61), the Vbe_Q2 (Vbe of transistor Q62), and the voltage drop across resistor R₆₂. The voltage drop across transistor R₆₂ is the product of the resistance of resistor R₆₂ and current IPTAT. Thus, the output bandgap voltage V_{BG} equals Vbe_Q1+Vbc_Q2+ (R₆₂*IPTAT). As described above, the Vbe of a BJT has a complementary to absolute temperature (CTAT) temperature dependence. Assuming the resistance of resistors R₆ₐ and R_{6b} are equal to each other and denoting that equal resistance as R₆, then current I₆₁, which equals current I₆₂, cquals Vr*In (N), where Vr is the transistor's thermal voltage, “In” is the natural logarithm operator, and “N” is the ratio of the sizes of transistors Q₆₁ and Q₆₂ as mentioned above. The transistor's thermal voltage, Vr, equals kT/q, “k” is the Boltzmann constant, “T” is temperature, “q” is electric charge of an electron. Because currents I₆₁ and I₆₂ are proportional to VT, currents I₆₁ and I₆₂ are PTAT currents. Because the currents I₆₁ and I₆₂, which combine to flow through resistor R₆₂, have a PTAT temperature dependence (and thus the voltage drop across resistor R₆₂ is PTAT) and the Vbe for each of transistors Q61 and Q64 have CTAT temperature dependencies, the output bandgap voltage VBG generally has very little dependence on temperature.

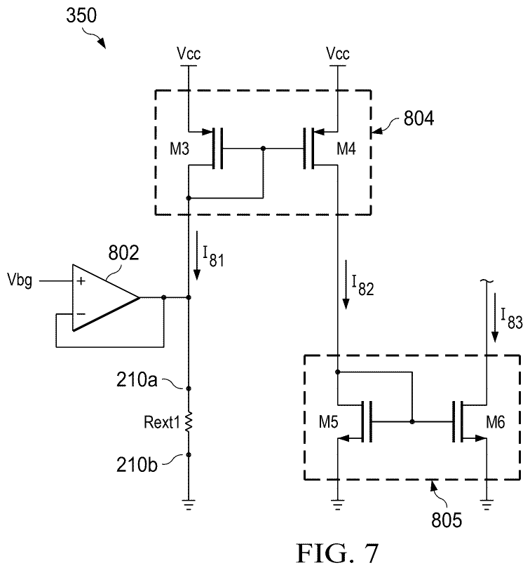

FIG. 7 is a schematic diagram of current source circuit 350. Current source circuit 350 in the example of FIG. 7 includes an OP AMP 802 and current mirrors 804 and 805. The output of OP AMP 802 is coupled to its negative input thereby operating OP AMP 802 as a unity gain buffer. The voltage Vbg from bandgap voltage reference circuit 330 is provided to the positive input of OP AMP 802. Resistor Rext1 is coupled between the output of OP AMP 802 (input 210a) and ground (input 210b). Current mirror 804 includes transistors M3 and M4. Transistors M1 and M2 are PFETs. The gates of transistors M3 and M4 are coupled together and to the output of OP AMP 802 and resistor Rext1. The sources of transistors M3 and M4 are coupled together and to Vcc. The current mirror ratio of current mirror 804 may be 1:1 or other than 1:1. The voltage at the output of OP AMP 802 is Vbg, thereby causing the voltage drop across resistor Rext1 to be Vbg. Current I₈₁ through resistor Rext1 is thus Vbg/Rext1. Current I₈₁ is mirrored by current mirror 804 as current I₈₂, which also is a function of (e.g., equal to) Vbg/Rext1. Current I₈₂ is then mirrored by current mirror 805, which includes NFETs M5 and M6. The output current from current mirror 805 is current I₈₃ which flows through the transistors that are on among transistor arrays 320 and 360, as described above.

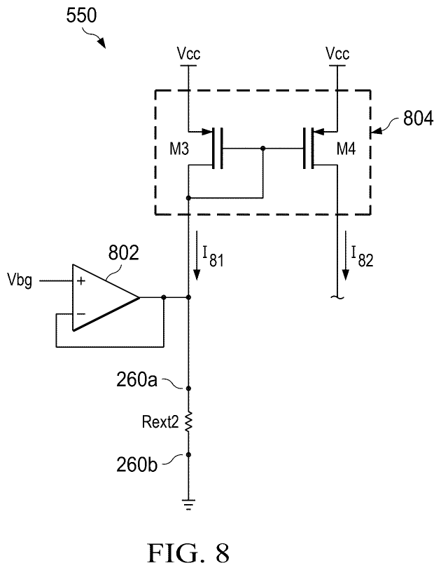

FIG. 8 is a schematic diagram of current source circuit 550. Current source circuit 550 is similar to that of FIG. 7 but lacks current mirror 805. In the example of FIG. 8, current source circuit 550 includes OP AMP 802 and current mirror 804. The output of OP AMP 802 is coupled to its negative input thereby operating OP AMP 802 as a unity gain buffer. The voltage Vbg from bandgap voltage reference circuit 530 is provided to the positive input of OP AMP 802. Resistor Rext2 is coupled between the output of OP AMP 802 and ground (inputs 260a and 260b). The voltage at the output of OP AMP 802 is Vbg, thereby causing the voltage drop across resistor Rext2 to be Vbg. Current I₈₁ through resistor Rext2 is thus Vbg/Rext2. Current I₈₁ is mirrored by current mirror 804 as current I₈₂, which also is a function of (e.g., equal to) Vbg/Rext2. Current I₈₂ flows through the transistors that are on among transistor arrays 520 and 560, as described above.

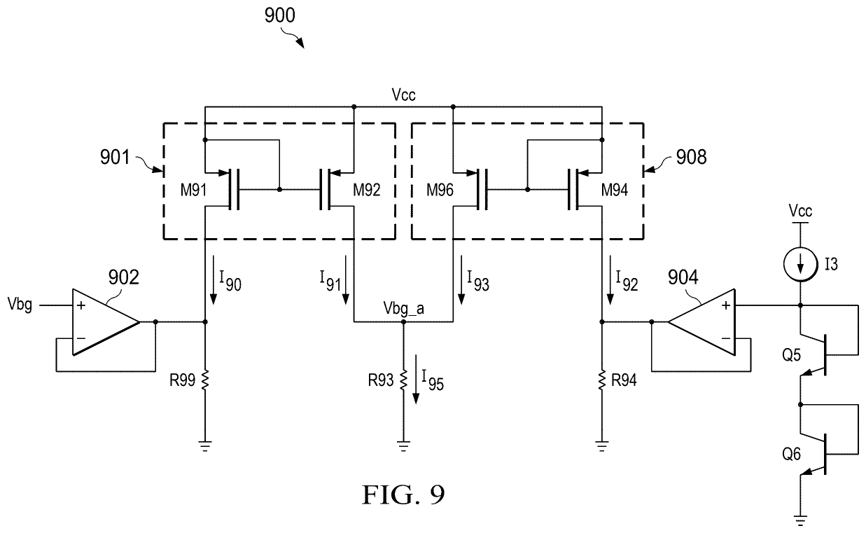

FIG. 9 is a schematic diagram of a circuit 900 coupled to the bandgap circuit of FIG. 6 which temperature-compensates the bandgap voltage Vbg to produce temperature-compensated bandgap voltage Vbg_a. Temperature-compensated bandgap voltage Vbg_a is provided to the negative input of comparator 370 (FIG. 3) and to the positive input of comparator 570 (FIG. 5). Current source circuits 350 and 550, however, generate their currents using the non-temperature-compensated bandgap voltage Vbg. Circuit 900 in FIG. 9 includes OP AMPs 902 and 904, current mirrors 901 and 908, resistors R93, R94, and R99, a current source circuit 13, and transistors Q5 and Q6. Current mirror 901 includes PFETs M91 and M92, and current mirror 908 includes PFETs M94 and M96. The drains of transistors M92 and M96 are coupled together and to resistor R93. Current I₉₀ through resistor R99 is equal to Vbg/R99. Current I₉₀ is mirrored by current mirror 901 as current I₉₁.

Transistors Q5 and Q6 are NPN BJTs configured as diode-connected transistors. The voltage drop across the stack of diode-connected transistors is a CTAT voltage, which is applied to the positive input of OP AMP 904. The output voltage from OP AMP 904 is provided across resistor R94. Accordingly, the current I₉₂ through resistor R94 is a CTAT current and is mirrored by current mirror 908 as current I₉₃. Current I₉₀, which is Vbg/R99 as described above, is combined with CTAT current I₉₃ to produce a current I₉₅. Current I₉₅ is a function of Vbg/R99 and has a CTAT characteristic as well.

Circuit 900 in FIG. 9 can be used for drivers for HS and LS transistors that have a significant temperature dependence. The CTAT characteristic of current I₉₅ produced by circuit 900 in FIG. 9 counteracts, to a large degree, the temperature dependence of the corresponding HS or LS transistor.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. An apparatus, comprising:
a first transistor having a control input; and
a driver having an output coupled to the control input, the driver including an adaptive slew rate control circuit having an input coupled to a first terminal, the adaptive slew rate control circuit configured to control the slew rate of the first transistor based on a resistor coupled to the first terminal.

2. The apparatus of claim 1, wherein the adaptive slew rate control circuit includes a bandgap voltage reference circuit, and the adaptive slew rate control circuit is configured to control the slew rate based on the resistor and a voltage produced by the bandgap voltage reference circuit.

3. The apparatus of claim 1, wherein the driver includes an array of first transistors coupled in parallel and to the control input, and the adaptive slew rate control circuit includes a corresponding number of second transistors coupled in parallel.

4. The apparatus of claim 3, wherein each of the second transistors is smaller than each of the first transistors.

5. The apparatus of claim 3, wherein the adaptive slew rate control circuit includes:
a bandgap voltage reference circuit configured to produce a voltage; and
a current source circuit coupled to each of the second transistors and to the bandgap voltage reference circuit, the current source circuit configured to provide a current through the second transistors based on the voltage and the resistor.

6. The apparatus of claim 5, wherein the adaptive slew rate control circuit determines which of the second transistors to turn on based on the voltage and the resistor.

7. The apparatus of claim 6, wherein each of the second transistors has a control input, and wherein the adaptive slew rate control circuit further includes:
a comparator having a first comparator input, a second comparator input, and a comparator output, the first comparator input coupled to the bandgap voltage reference circuit, the second comparator input coupled to the second transistors; and
a logic circuit having an input coupled to the comparator output, a clock input, and outputs coupled to respective control inputs of the second transistors.

8. The apparatus of claim 7, wherein the logic circuit is configured to control an on and off state of each of the second transistors based on a signal at the comparator output.

9. The apparatus of claim 7, wherein the logic circuit is configured to:
determine a number of the second transistors to turn on based on a signal at the output of the comparator; and
determine a corresponding number of the first transistors to turn on.

10. The apparatus of claim 1, wherein the adaptive slew rate control circuit is a first adaptive slew rate control circuit having outputs, and the driver includes:
an array of first transistors coupled in parallel and to the control input, each of the first transistors having a control input coupled to a corresponding output of the first adaptive slew rate control circuit;
a second adaptive slew rate control circuit having outputs; and
an array of second transistors coupled in parallel and to the control input, each of the second transistors having a control input coupled to a corresponding output of the second adaptive slew rate control circuit.

11. An apparatus, comprising:
transistors having control inputs, first terminals, and second terminals, the first terminals coupled together and the second terminals coupled together;
a bandgap voltage reference circuit having a first voltage terminal coupled to the first terminals and having a second voltage terminal;
a comparator having a first comparator input, a second comparator input, and a comparator output, the first comparator input coupled to the second voltage terminal, and the second comparator input coupled to the second terminals;
a current source circuit coupled to the second terminals; and
a logic circuit having an input coupled to the comparator output and having outputs coupled to respective control inputs of the transistors.

12. The apparatus of claim 11, wherein the logic circuit has a clock input.

13. The apparatus of claim 11, further including a third terminal and a fourth terminal, and wherein the current source circuit is configured to provide a current through the second terminals based on a voltage at the second voltage terminal and a resistor coupled to the third and fourth terminals.

14. The apparatus of claim 13, further comprising a complementary to absolute temperature (CTAT) circuit coupled to the bandgap voltage reference circuit.

15. The apparatus of claim 11, wherein the logic circuit determines a number of the transistors to turn on based on a signal at the comparator output.

16. The apparatus of claim 11, wherein the transistors include:
a set of first transistors; and
a set of second transistors, the second transistors being smaller than the first transistors.

17. A power converter, comprising:
a first transistor having a control input;
a second transistor coupled to the first transistor and having a control input;
a first driver having an output coupled to the control input of the first transistor, the first driver including a first adaptive slew rate control circuit having an input coupled to a first terminal, the first adaptive slew rate control circuit configured to control the slew rate of the first transistor based on a first resistor coupled to the first terminal; and
a second driver having an output coupled to the control input of the second transistor, the second driver including a second adaptive slew rate control circuit having an input coupled to a second terminal, the second adaptive slew rate control circuit configured to control the slew rate of the second transistor based on a second resistor coupled to the second terminal.

18. The power converter of claim 17, wherein:
the first adaptive slew rate control circuit includes a first bandgap voltage reference circuit, and the first adaptive slew rate control circuit is configured to control the slew rate of the first transistor based on the first resistor and a voltage produced by the first bandgap voltage reference circuit; and
the second adaptive slew rate control circuit includes a second bandgap voltage reference circuit, and the second adaptive slew rate control circuit is configured to control the slew rate of the second transistor based on the second resistor and a voltage produced by the second bandgap voltage reference circuit.

19. The power converter of claim 18, wherein:
the first adaptive slew rate control circuit includes:
a first array of transistors having first terminals coupled together and to the second bandgap voltage reference circuit and having second terminals coupled together; and
a first comparator having a first comparator input coupled to the first bandgap voltage reference circuit and having a second comparator input coupled to the second terminals of the first array of transistors; and
the second adaptive slew rate control circuit includes:
a second array of transistors having first terminals coupled together and to the second bandgap voltage reference circuit and having second terminals coupled together; and
a second comparator having a first comparator input coupled to the second bandgap voltage reference circuit and having a second comparator input coupled to the second terminals of the second array of transistors.

20. The power converter of claim 19, wherein each transistor of the first array of transistors has a control input, each transistor of the second array of transistors has a control input, the first comparator has a comparator output, and the second comparator has a comparator output, and wherein:
the first adaptive slew rate control circuit includes a first logic circuit having an input coupled to the output of the first comparator and having outputs coupled to respective control inputs of the first array of transistors; and
the second adaptive slew rate control circuit includes a second logic circuit having an input coupled to the output of the second comparator and having outputs coupled to respective control inputs of the second array of transistors.
